(19) United States
(12) Patent Application Publication
(10) Pub. No.: US 2014/0131688 A1
(43) Pub. Date: May 15, 2014

(54) INTERCONNECTION STRUCTURE INCLUDING REFLECTIVE ANODE ELECTRODE FOR ORGANIC EL DISPLAYS

(71) Applicants: Hiroyuki Okuno, Kobe-shi (JP); Aya Miki, Kobe-shi (JP); Toshihiro Kugimiya, Kobe-shi (JP)

(72) Inventors: Hiroyuki Okuno, Kobe-shi (JP); Aya Miki, Kobe-shi (JP); Toshihiro Kugimiya, Kobe-shi (JP)

(73) Assignee: Kabushiki Kaisha Kobe Seiko Sho (Kobe Steel, Ltd.), Chuo-ku, Kobe-shi (JP)

(21) Appl. No.: 14/115,264

(22) PCT Filed: May 18, 2012
(86) PCT No.: PCT/JP12/62867

§ 371 Date: Nov. 1, 2013

(30) Foreign Application Priority Data
May 24, 2011 (JP) 2011-116304
May 24, 2011 (JP) 2011-116305
May 24, 2011 (JP) 2011-116306

(51) Int. Cl. H01L 27/32

(52) U.S. Cl. CPC H01L 27/3276
USPC 257/40

(57) ABSTRACT

Provided is an interconnection structure comprising a reflective anode electrode for organic EL displays, which is provided with an Al alloy film that has excellent durability and is capable of assuring stable light emission characteristics even in cases where an Al reflective film is directly connected with an organic layer, while achieving high yield. The present invention is related to an interconnection structure which comprises, on a substrate, an Al alloy film that constitutes a reflective anode electrode for organic EL displays and an organic layer that contains a light-emitting layer. In the interconnection structure, the Al alloy film contains a specific rare earth element in an amount of 0.05-5% by atom and the organic layer is directly connected onto the Al alloy film.

### TECHNICAL FIELD

The present invention relates to an interconnection structure including a reflective anode electrode for use in an organic electro-luminescence display (particularly, a top-emission-type organic EL display).

### BACKGROUND ART

An organic electroluminescence (hereinafter, referred to as “organic EL”) display, as one of self-luminous flat panel displays, is an all-solid-type flat panel display in which organic EL devices are arranged in a matrix on a substrate such as a glass. In the organic EL display, anodes and cathodes are each provided in a stripe pattern, and each of intersections of the anodes and the cathodes corresponds to a pixel (an organic EL device). A voltage of several volts is externally applied to the organic EL device for current flow therethrough, so that organic molecules are each raised to an excited state. The excited organic molecule returns to an original ground state (stable state) while emitting excess energy in a form of light.

The organic EL device is a self-luminous and current-drive device, and a drive method thereof includes a passive type and an active type. The passive type allows a simple device structure, but is less likely to achieve full-color display. On the other hand, the active type enables a large size display, and is suitable for full-color display. The active type, however, requires a TFT substrate. Such a TFT substrate includes TFTs including low-temperature polycrystalline Si (p-Si) or amorphous Si (a-Si).

In the case of the active-type organic EL display, usable area for organic EL pixels is small due to presence of a plurality of TFTs and interconnections. When a drive circuit is complicated and the number of TFTs increases, the TFTs further greatly affect the usable area. Recently, attention is focused on a technique for increasing an open area ratio through a structure (top emission type) that allows light to be extracted from a top side rather than to be extracted through a glass substrate.

In the top emission type, ITO (Indium-Tin Oxide) having excellent hole injection capability is used for an anode on a bottom. Although a transparent conductive film must also be used for a cathode on a top, ITO is not suitable for electron injection due to its large work function. Furthermore, since ITO is deposited by a sputtering process or an ion beam evaporation process, an electron transport layer (one of organic materials configuring the organic EL device) is possibly damaged by plasma ions or secondary electrons during deposition of ITO. Thus, a thin Mg layer or a thin copper phthalocyanine layer is provided on the electron transport layer in order to avoid such damage and improve electron injection.

An anode electrode for use in such an active-matrix top-emission organic EL display is formed into a stacked structure of a transparent oxide conductive film typically including ITO or IZO (Indium-Zinc Oxide) and a reflective film for reflecting light emitted from each organic EL device (a reflective anode electrode). The reflective film used in the reflective anode electrode is often a reflective metal film including molybdenum (Mo), chromium (Cr), aluminum (Al), or silver (Ag). For example, a stacked structure of ITO and an Ag alloy film is used for the reflective anode electrode of the top-emission-type organic EL display.

In consideration of reflectance, Ag or Ag-based alloy mainly containing Ag is useful because of its high reflectance. Although the Ag-based alloy has a unique problem of inferior corrosion resistance, such a problem can be solved by covering the Ag-based alloy film with an ITO film stacked thereon. In the case of Ag, however, material cost is high, and a sputtering target necessary for deposition is less likely to be increased in size. It is therefore difficult to use the Ag-based alloy film as a reflective film of the active-matrix top-emission organic EL display for a large-size display.

In light of only reflectance, Al is also preferred for the reflective film. For example, PTL1 discloses an Al film or Al—Nd film as the reflective film, describing that the Al—Nd film desirably has high reflective efficiency.

However, when the Al reflective film is made into direct contact with the oxide conductive film including ITO or IZO, contact resistance is high, which prevents supply of sufficient current for hole injection into the organic EL device. To avoid this, high-melting-point metal such as Mo or Cr may be used for the reflective film instead of Al, or the high-melting-point metal such as Mo or Cr may be provided as barrier metal between the Al reflective film and the oxide conductive film. In such a case, unfortunately, reflectance is significantly reduced, leading to a reduction in emission luminance as one display characteristic.

Thus, PTL2 proposes an Al—Ni alloy film, which contains Ni in an amount of 0.1 to 2 at %, as a reflective electrode (reflective film) allowing the barrier metal to be omitted. Such an Al—Ni alloy film has a high reflectance similar to that of pure Al, and enables low contact resistance even if the Al reflective film is made into direct contact with the oxide conductive film including ITO or IZO.

### CITATION LIST

### Patent Literature

PTL1: Japanese Unexamined Patent Application Publication No. 2005-259695.
PTL2: Japanese Unexamined Patent Application Publication No. 2008-122941.

### SUMMARY OF THE INVENTION

### Problems that the Invention is to Solve

In the top-emission organic EL display, when hole injection from the anode into the organic layer as an upper layer is considered, since holes are transferred from the highest occupied molecular orbital (HOMO) of the anode material to the HOMO of the organic layer, an energy difference between such orbitals becomes an injection barrier. Although ITO having a low energy barrier is currently used for volume production, if the work function of ITO is reduced due to the influence of a layer under the ITO, such an energy barrier becomes high. For example, while the reflective anode electrode for the top-emission-type organic EL display has the stacked structure (an ITO upper layer/an Al-alloy lower layer) of the oxide conductive film including ITO (hereinafter, represented as ITO in some cases) and the Al reflective film (or Al-alloy reflective film), a work function of the surface of the ITO film in the stacked structure is disadvantageously about 0.1 to 0.2 eV lower than that of the stacked structure (an ITO upper layer/an Ag-based-alloy lower layer) being currently volume-produced. Although the detailed reason for this is unclear, if the work function of the ITO film surface is reduced by about 0.1 to 0.2 eV, an emission start voltage (a threshold voltage) of the organic light-emitting layer formed as an upper layer of the ITO film is shifted by about several voltages to a high voltage side. Thus, when the same emission intensity is maintained, power consumption is increased.

Moreover, the organic EL display has a problem of uneven emission intensity caused by a pinhole in the ITO film and in-plane variation in contact property between the ITO film and the Al reflective film, etc.

To cope with such problems, an organic layer, which allows direct connection of the Al reflective film with the organic layer without the ITO film, is being developed.

However, the Al reflective film is left uncovered in a period before formation of the organic layer under a situation where the ITO film protecting the Al reflective film does not exist. Hence, for example, while a substrate having the Al reflective film thereon is conveyed, a dent may be locally formed in the substrate by longitudinal deformation (stress) due to, for example, shock from the upper side, so that the Al reflective film tends to have an abnormal concave shape etc. in its surface. This disadvantageously results in electric field concentration in the periphery of such a concave portion, leading to uneven emission intensity, and results in a reduction in life of the light emitting device.

An object of the present invention, which has been made in light of the above-described circumstance, is to provide an interconnection structure containing a reflective anode electrode for organic EL displays, the reflective anode electrode including an Al-alloy reflective film that is particularly excellent in durability against longitudinal stress, allows stable emission characteristics without uneven emission intensity to be ensured even if the Al reflective film is directly connected to an organic layer, and enables a high production yield.

### Means for Solving the Problems

The present invention provides an interconnection structure, a thin film transistor, and an organic EL display as described below.

(1) An interconnection structure including, on a substrate, an Al alloy film configuring a reflective anode electrode for organic EL displays and an organic layer containing a light emitting layer, the interconnection structure being characterized in that the Al alloy film contains at least one rare earth element in an amount of 0.05 to 5 at %, the rare earth element being selected from a group consisting of Nd, Gd, La, Y, Ce, Pr, and Dy, and the organic layer is directly connected onto the Al alloy film.

(2) The interconnection structure according to (1), characterized in that the Al alloy film has a hardness of 2 to 3.5 GPa and a density of grain boundary triple points in an Al alloy structure of 2×10⁸/mm² or more.

(3) The interconnection structure according to (1) or (2), characterized in that the Al alloy film has a Young's modulus of 80 to 200 GPa and a maximum value of one-direction tangential diameter (Feret diameter) of a crystal grain of 100 to 350 nm.

(4) The interconnection structure according to any one of (1) to (3), characterized in that the Al alloy film has a glossiness of 800% or more.

(5) The interconnection structure according to any one of (1) to (4), wherein the Al alloy film is electrically connected to a source/drain electrode of a thin film transistor formed on the substrate.

(6) A thin film transistor substrate, including the interconnection structure according to any one of (1) to (5).

(7) An organic EL display, including the thin film transistor substrate according to (6).

### Advantageous Effects of the Invention

According to the present invention, an Al alloy film, which contains a rare earth element and is appropriately controlled in hardness and in density of grain boundary triple points, is used as an Al alloy film configuring a reflective anode electrode for organic EL displays, and therefore the Al alloy film is particularly excellent in durability against longitudinal stress such as an indentation load. In addition, since the Al alloy film is appropriately controlled in Young's modulus and in maximum grain size along the one-direction tangential diameter (Feret diameter) of a crystal grain, the Al alloy film is also excellent in durability against lateral deformation. As a result, even if the Al reflective film is directly connected to the organic layer, stable emission characteristics can be ensured, so that a highly reliable, reflective anode electrode for organic EL displays has been able to be provided. Furthermore, since the Al alloy film is excellent in glossiness, a reflective anode electrode for organic EL displays, which is excellent in color expression power, has been able to be provided. The organic EL display of the present invention is preferably used for, for example, a mobile phone, a portable video game player, a tablet computer, and a television.

### BRIEF DESCRIPTION OF THE DRAWINGS

FIG. 1 is a schematic view illustrating a traditional organic EL display including a reflective anode electrode of the present invention.

### MODE FOR CARRYING OUT THE INVENTION

The inventors have made various investigations in order to provide an electrode material being generally used as a reflective anode electrode for organic EL displays, i.e., an Al alloy film containing a rare earth element (hereinafter, abbreviated to Al-rare earth element alloy film or simply Al alloy film in some cases), which has appropriate durability against each of longitudinal deformation (stress) and lateral deformation (stress) generated as by shock from the upper side during, for example, conveyance of a substrate having the Al alloy film thereon even if the Al alloy film is directly connected to the organic layer without the oxide conductive film, and thus can prevent formation of a dent associated with such deformation, and can prevent degradation in emission characteristics and reduction in service life. As a result, the inventors have found that when an Al alloy film having predetermined hardness and grain boundary density is used as the Al-rare earth element alloy film, the expected purpose is attained.

Specifically, in the invention, from the viewpoint of ensuring stable emission characteristics even if the Al reflective film is directly connected to the organic layer, and ensuring high reliability, an Al-rare earth element alloy film being an Al alloy film containing a rare earth element, of which the hardness is 2 to 3.5 GPa, and the density of the grain boundary triple points in the Al alloy structure is 2×10⁸/mm² or more, can be used as the Al alloy film for the reflective anode electrode for organic EL displays.

In addition, an Al-rare earth element alloy film may be configured such that the Al alloy film has a Young's modulus of 80 to 200 GPa and a maximum value of one-direction tangential diameter (Feret diameter) of a crystal grain of 100 to 350 nm. Furthermore, the Al alloy film may have a glossiness of 800% or more.

First, the Al-rare earth element alloy film preferably has a hardness of 2 to 3.5 GPa. As described above, unlike in the past, the Al alloy film of the invention is used while being directly connected to the organic light-emitting layer without the oxide conductive film such as ITO stacked thereon. To achieve this, the reflective anode electrode for organic EL displays is required to have sufficient durability against longitudinal stress to prevent formation of a dent etc. on the electrode even if the electrode is deformed or degraded due to temporarily concentrated stress. From such a viewpoint, the above-described hardness is set further considering hardness of the Al alloy film being stacked with the oxide conductive film such as ITO, and considering hardness balance to the glass substrate etc.

In detail, if an electrode material configuring the electrode is too soft, the electrode is deformed due to stress concentration, which may cause troubles such as uneven light emission. On the other hand, if the electrode material is too hard, the electrode is less likely to be deformed by an indentation load, which may cause microcracks or degradation such as separation in the material. In the case where the Al alloy film is used as the electrode material while being not stacked with the oxide conductive film such as ITO, consideration must be further made on hardness balance between the Al alloy film itself and a stack of the Al alloy film and the oxide conductive film to set hardness of the Al alloy film. That is, the upper limit of the hardness of the Al alloy film is preferably controlled to be roughly similar to the hardness of the stack, while the lower limit thereof is preferably not significantly different from the hardness of the substrate typically including a glass substrate. On the basis of such a viewpoint, the invention specifies preferable hardness of the Al alloy film to be 2 to 3.5 GPa. The hardness is more preferably 2.5 to 3.3 GPa. The values of the hardness of the Al alloy film are determined according to a procedure mentioned in Examples described later.

Furthermore, the Al alloy film used in the invention satisfies density of grain boundary triple points (hereinafter, abbreviated to triple point density in some cases) in the Al alloy structure of 2×10⁸/mm² or more. As described above, in the invention, the hardness of the Al alloy film is preferably controlled to be within a predetermined range. In general, hardness is closely related with triple point density, and when the content of the rare earth element is within a range (5 at % or less) of the invention, hardness tends to increase with increase in triple point density. In the invention, the triple point density is specified to be 2×10⁸/mm² or more in light of ensuring the lower limit (2 GPa) of the hardness of the Al alloy film. The triple point density is preferably 2.4×10⁸/mm² or more. The upper limit of the triple point density is preferably 8.0×10⁸/mm² in consideration of efficiency of sputtering deposition. The values of the triple point density of the Al alloy film are determined according the following procedure as mentioned in the Example described later. Specifically, the Al alloy film is subjected to TEM observation at a magnification of 150,000× to measure density (triple point density) of Al alloy at a grain boundary triple point observed in each of measured visual fields (each visual field being 1.2 μm×1.6 μm). Such measurement is performed in three visual fields in total, and the average of the measured values is determined as the triple point density of the Al alloy.

The Al alloy film used in the invention contains the rare earth element in an amount of 0.05 to 5 at % with the remainder being Al and inevitable impurities. The Al alloy film containing the rare earth element has heat resistance. There has not been disclosed an Al alloy film that is controlled in hardness and triple point density in light of providing a material suitable for the reflective anode electrode for organic EL displays. The lower limit and the upper limit of the content of the rare earth element are each specified to ensure the range of each of the hardness and the triple point density specified in the invention. As shown in the Examples described later, the hardness tends to decrease with a decrease in content of the rare earth element. If the content of the rare earth element is below the lower limit specified in the invention, at least one of the hardness and the triple point density is out of the range of the invention. On the other hand, the hardness tends to increase with increase in content of the rare earth element. If the content of the rare earth element exceeds the upper limit specified in the invention, at least one of the hardness and the triple point density is out of the range of the invention.

The inevitable impurities include Fe, Si, and Cu, each of which is allowed to be contained in an amount of 0.05 wt % or less. If the content of each inevitable impurity is out of the above-described range, corrosion resistance may be degraded. The inevitable impurities further include oxygen, which is allowed to be contained in an amount of 0.1 wt % or less. If the content of oxygen is out of the above-described range, electric resistance may disadvantageously increase.

In the invention, from the viewpoint of ensuring stable emission characteristics even if the Al reflective film is directly connected to the organic layer, and ensuring high reliability, an Al-rare earth element alloy film being an Al alloy film containing a rare earth element, of which the Young's modulus is 80 to 200 GPa, and the maximum value of the one-direction tangential diameter (Feret diameter) of a crystal grain is 100 to 350 nm, can be used as the Al alloy film for the reflective anode electrode for organic EL displays.

First, the Al-rare earth element alloy film is preferably has a Young's modulus of 80 to 200 GPa. As described above, unlike in the past, the Al alloy film of the invention is used while being directly connected to the organic light-emitting layer without the oxide conductive film such as ITO stacked thereon. To achieve this, the reflective anode electrode for organic EL displays is required to have sufficient durability against lateral stress to prevent formation of asperities etc. on the electrode even if the electrode is deformed or degraded due to temporarily concentrated stress. From such a viewpoint, the above-described Young's modulus is set further considering a Young's modulus of the Al alloy film being stacked with the oxide conductive film such as ITO, and considering balance of Young's modulus to the glass substrate etc.

In detail, if an electrode material configuring the electrode has a small Young's modulus (i.e., is too soft), the electrode is deformed due to stress concentration, which may cause troubles such as uneven light emission. On the other hand, if the electrode material has a large Young's modulus (i.e., is too hard), the electrode is less likely to be deformed by an indentation load, which may cause microcracks or degradation such as separation in the material. In the case where the Al alloy film is used as the electrode material while being not stacked with the oxide conductive film such as ITO, consideration must be further made on balance between the Young's modulus of the Al alloy film itself and the Young's modulus of a stack of the Al alloy film and the oxide conductive film to set the Young's modulus of the Al alloy film. That is, the upper limit of the Young's modulus of the Al alloy film is preferably controlled to be roughly similar to the Young's modulus of the stack, while the lower limit thereof is preferably not significantly different from the Young's modulus of the substrate typically including a glass substrate. On the basis of such a viewpoint, the invention specifies preferable Young's modulus of the Al alloy film to be 80 to 200 GPa. The Young's modulus is more preferably 85 to 180 GPa. The values of the Young's modulus of the Al alloy film are determined according to the following procedure, as mentioned in the Examples described later. Specifically, a hardness test of a film is performed by a nano-indenter to determine the Young's modulus. In this test, the Al alloy film is subjected to continuous stiffness measurement using an XP tip with Nano Indenter G200 from Agilent Technologies Co., Ltd (analysis software: Test Works 4). The value of the Young's modulus is determined by taking the average of the resultant values of measurement at 15 points with indentation depth of 500 nm.

Furthermore, the maximum grain size (the maximum value of one-direction tangential diameter (Feret diameter) of a crystal grain) of the Al alloy film used in the invention satisfies 100 to 350 nm. As described above, in the invention, the Young's modulus of the Al alloy film must be controlled to be within a predetermined range. In general, a Young's modulus is roughly closely related with the maximum grain size, and when the content of the rare earth element is within a range (5 at % or less) of the invention, the Young's modulus tends to decrease with increase in maximum grain size. In the invention, the upper limit of the maximum grain size is specified to be 350 nm in light of ensuring the lower limit (80 GPa) of the Young's modulus of the Al alloy film, and the lower limit of the maximum grain size is specified to be 100 nm in light of ensuring the upper limit (200 GPa) of the Young's modulus of the Al alloy film. The preferable maximum grain size is 130 to 320 nm.

The maximum grain size refers to the maximum value of the one-direction tangential diameter (called Feret diameter or Green diameter) of a crystal grain. Specifically, the maximum grain size refers to an interval (a distance) between two parallel lines in a certain direction with a grain therebetween. When the crystal grain has a dent, the maximum grain size corresponds to a distance between parallel external tangents on a projection drawing. When the crystal grain has no dent (has a spherical shape), the maximum grain size corresponds to a value obtained by dividing a circumferential length by π. The value of the maximum grain size is specifically determined in the following way. That is, the Al alloy film is subjected to TEM observation at a magnification of 150,000× to measure grain size (one-direction tangential diameter, or Feret diameter) of each crystal grain observed in each of measured visual fields (each visual field being 1.2 μm×1.6 μm). Such measurement is performed in three visual fields in total, and the maximum of the values obtained in the three visual fields is determined as the maximum grain size.

Description has been made on the Young's modulus and the maximum grain size of the Al alloy film characterizing the present invention. The Al alloy film used in the invention contains the rare earth element in an amount of 0.05 to 5 at % with the remainder being Al and inevitable impurities. The Al alloy film containing the rare earth element has heat resistance. There has not been disclosed an Al alloy film that is controlled in Young's modulus and maximum grain size in light of providing a material suitable for the reflective anode electrode for organic EL displays. The lower limit of the content of the rare earth element is specified to ensure the range of each of the hardness and the triple point density specified in the invention. The lower limit is specified in order to allow the heat resistance effect to be effectively exhibited, while the upper limit thereof is specified to ensure the range of each of the Young's modulus and the maximum grain size specified in the invention. As the content of the rare earth element increases, the Young's modulus tends to increase, but the maximum grain size tends to decrease.

The inevitable impurities include Fe, Si, and Cu, each of which is allowed to be contained in an amount of 0.05 wt % or less. If the content of each of the inevitable impurities is out of the above-described range, corrosion resistance may be degraded. The inevitable impurities further include oxygen, which is allowed to be contained in an amount of 0.1 wt % or less. If the content of oxygen is out of the above-described range, electric resistance may disadvantageously increase.

Through investigations, the inventors have found that (1) glossiness of the electrode greatly affects the hue of the organic EL display, and in the case where each crystal grain of the Al alloy film has a large grain size (in detail, a large maximum value of the one-direction tangential diameter called Feret diameter), or in the case where the density of the crystal grain is small, glossiness of the Al alloy film is reduced, resulting in inferior color expression power of the organic EL display, (2) in detail, the glossiness of the Al alloy film is substantially determined by size and/or density of the grain size immediately after deposition, and the glossiness is almost unvaried through heat treatment (annealing) after deposition, and (3) appropriate control of deposition conditions (preferably, temperature and Ar gas pressure during the sputtering) is effective to achieve high glossiness. Furthermore, the inventors have found that the content of the rare earth element in the Al alloy film is also closely related with the glossiness of the Al alloy film, where (4) although the glossiness tends to increase with increase in content of the rare earth element, if a large amount of rare earth element is added, the hue of the organic EL display is degraded due to a disadvantageous etching characteristic; hence, the upper limit of the content is effectively controlled to be 5 at %, and (5) such an Al alloy film, which is appropriately controlled in glossiness and content of the rare earth element, may be singly used, or may be used in a form of a stacked material in which a high-melting-point metal film such as a Mo film is stacked on the bottom of the Al alloy film.

In this way, the glossiness of the Al-rare earth alloy film used in the invention is preferably 800% or more. Thus, the color expression power of the organic EL display is also improved. While higher glossiness is more advantageous, the glossiness is preferably 805% or more. The upper limit of the glossiness of the Al alloy film, which is not particularly specified, is about 840% in consideration of conditions (such as the content of the rare earth element in the Al alloy film and a manufacturing condition of the Al alloy film, as described in detail later) for ensuring the desired glossiness. The values of the glossiness of the Al alloy film are determined according to the following procedure, as mentioned in the Examples described later. Specifically, 60° specular glossiness is measured in accordance with JIS K7105-198. The glossiness is represented by a value (%) obtained assuming that glossiness of the surface of glass having a refractive index of 1.567 is 100.

The Al alloy film used in the invention contains the rare earth element in an amount of 0.05 to 5 at % with the remainder being Al and inevitable impurities. The Al alloy film containing the rare earth element has heat resistance. There has not been disclosed an Al alloy film that is appropriately controlled in glossiness and content of the rare earth element in light of providing a material suitable for the reflective anode electrode for organic EL displays. The lower limit of the content of the rare earth element is specified to allow the heat resistance effect to be effectively exhibited, while the upper limit thereof is specified to ensure the lower limit of the glossiness specified in the invention. Specifically, as shown in the Examples described later, the glossiness of the Al alloy film is closely related with the content of the rare earth element, and in the case where the Al alloy films are fabricated in the same conditions, the glossiness of the Al alloy film tends to increase with increase in content of the rare earth element. However, an excessively large content of the rare earth element causes a new problem of etching characteristics, leading to degradation in hue. Hence, the upper limit of the content is specified to be 5 at %. In addition, if the content of the rare earth element is within the above-described range, electric resistance of an interconnection can be controlled to be low.

The inevitable impurities include Fe, Si, and Cu, each of which is allowed to be contained in an amount of 0.05 wt % or less. If the content of each inevitable impurity is out of the above-described range, corrosion resistance may be degraded. The inevitable impurities further include oxygen, which is allowed to be contained in an amount of 0.1 wt % or less. If the content of oxygen is out of the above-described range, electric resistance may disadvantageously increase.

The rare earth elements used in the invention include an element group consisting of lanthanoid elements (15 elements in total from La (atomic number 57) to Lu (atomic number 71) in the Periodic Table), Sc (scandium), and Y (yttrium). In the invention, such elements may be used singly, or two or more of the elements may be used in combination. The above-described content of the rare earth element refers to the content of a single element in the case where the element is singly used, and refers to the total content of two or more elements in the case where such elements are used in combination. A preferable rare earth element includes at least one element selected from a group consisting of Nd, Gd, La, Y, Ce, Pr, and Dy.

The upper limit of the content of the at least one element (in particular, Nd) selected from the group consisting of Nd, Gd, La, Y, Ce, Pr, and Dy is preferably 1 at % in light of controlling each of the hardness and the triple point density to be within a predetermined range.

In the invention, the Al alloy film may be used singly, or may be used in a form of a stacked structure where a high-melting-point metal film is stacked on the bottom of the Al alloy film, as the electrode material. The high-melting-point metal film is generally used to prevent oxidation of Al, and Mo, Ti, Cr, and W or an alloy mainly including each of such metals may be used in the invention.

The preferable thickness of the Al alloy film is roughly 50 to 700 nm. In the case where the Al alloy film is singly used, the preferable thickness is roughly 50 to 600 nm. In the case where the Al alloy film is used in a form of a stacked structure with the high-melting-point metal film, the preferable total thickness (of the high-melting-point metal film and the Al alloy film in order of closeness to a substrate) is roughly 80 to 700 nm. At this time, the preferable thickness of the Al alloy film is roughly 50 to 600 nm, while the preferable thickness of the high-melting-point metal film is roughly 30 to 100 nm.

In the invention, to achieve the Al alloy film that is appropriately controlled in hardness and triple point density, the Al alloy film containing the predetermined rare earth element is preferably used, and besides the deposited Al alloy film is preferably heat-treated (annealed) within a temperature range from room temperature to 230° C. In a manufacturing process of the organic EL display after formation of the reflective film, a semi-product of the organic EL display is often subjected to thermal history from room temperature to about 250° C. In case of a high annealing temperature, a reduction in hardness and in triple point density is caused due to precipitation of the rare earth element and grain growth of the Al alloy. Specifically, the annealing temperature should be appropriately set depending on the added amount of the rare earth element, and is preferably 150 to 230° C.

Examples of the deposition process of the Al alloy film include a sputtering process and a vacuum evaporation process. In the invention, the Al alloy film is preferably formed by the sputtering process in light of fining, homogenization of each alloy component in the film, and ease in control of the amount of the added element. In the sputtering process, it is preferred that deposition temperature during the sputtering is controlled to be roughly 180° C. or less, and Ar gas pressure is controlled to be roughly 3 mTorr or less. As the substrate temperature or the deposition temperature is higher, quality of the formed film is closer to that of a bulk, a dense film is thus more readily formed, and hardness of the film tends to increase. In addition, as the Ar gas pressure is increased, density of the film tends to be reduced, leading to a decrease in hardness of the film. Such adjustment of the deposition conditions is also preferred in light of suppressing easy occurrence of corrosion due to roughening of a film structure.

In the invention, to achieve the Al alloy film that is appropriately controlled in Young's modulus and maximum grain size, appropriate control of sputtering conditions is preferred in addition to use of the Al alloy film containing the predetermined rare earth element. Specifically, examples of the deposition process of the Al alloy film include a sputtering process and a vacuum evaporation process. In the invention, the Al alloy film is recommended to be formed by the sputtering process in light of fining, homogenization of each alloy component in the film, and ease in control of the amount of the added element. In addition, it is preferred that deposition temperature during the sputtering is controlled to be roughly 230° C. or less, and Ar gas pressure is controlled to be roughly 20 mTorr or less. Moreover, the substrate temperature during the sputtering is preferably controlled to be roughly 180° C. or less. As the substrate temperature or the deposition temperature is higher, quality of the formed film is closer to that of a bulk, and thus a dense film is more readily formed, and the Young's modulus of the film tends to increase. In addition, as the Ar gas pressure is increased, density of the film tends to be reduced, leading to a decrease in Young's modulus of the film. Such adjustment of the deposition conditions is also preferred in light of suppressing easy occurrence of corrosion due to roughening of a film structure.

The Al alloy film deposited by the sputtering process as described above is preferably heat-treated (annealed) within a temperature range from room temperature to 230° C. In a manufacturing process of the organic EL display, a semi-product of the organic EL is often subjected to thermal history from room temperature to about 250° C. after formation of the reflective film. A high annealing temperature, however, causes a reduction in Young's modulus and in maximum grain size due to precipitation of the rare earth element and grain growth of the Al alloy. Specifically, the annealing temperature should be appropriately set depending on the added amount of the rare earth element, and is preferably 150 to 230° C.

In the invention, to achieve the Al alloy film that is appropriately controlled in glossiness, appropriate control of sputtering conditions is preferred in addition to use of the Al alloy film containing the predetermined rare earth element. Specifically, examples of the deposition process of the Al alloy film include a sputtering process and a vacuum evaporation process. In the invention, the Al alloy film is recommended to be formed by the sputtering process in light of fining, homogenization of each alloy component in the film, and ease in control of the amount of the added element. In addition, it is preferred that deposition temperature during the sputtering is controlled to be roughly 270° C. or less, and Ar gas pressure is controlled to be roughly 15 mTorr or less. Moreover, the substrate temperature during the sputtering is preferably controlled to be roughly 270° C. or less. The reason for this is that as the substrate temperature or the deposition temperature is higher, sputtered particles more easily move on a substrate surface, which causes formation of coarse crystal grain size, resulting in a reduction in glossiness. In addition, as the Ar gas pressure is increased, collision frequency of the sputtered particles to Ar gas increases. As a result, energy of each sputtered particle is reduced at arrival at the substrate, and in turn density of crystal grains decreases, resulting in a reduction in glossiness.

The glossiness of the Al alloy film (that has been just) deposited under the above-described preferable sputtering conditions is as high as 800% or more. Such high glossiness is maintained regardless of conditions of subsequent heat treatment (annealing). In this regard, the glossiness is significantly different from the reflectance that is strongly influenced by the state (such as size and density of crystal grains) of the heat-treated Al alloy film. In a manufacturing process of the organic EL display, a semi-product of the organic EL display is often subjected to thermal history from room temperature to about 250° C. Even if the annealing temperature exceeds the above-described temperature range, for example, even if annealing is performed at 300° C., the glossiness of the heat-treated Al alloy film maintains a high level of 800% or more (see the Examples described later). In consideration of heat resistance of resin, however, preferable annealing temperature is 150 to 230° C.

The invention is characterized by the electrode including the Al alloy film to be directly connected to the organic layer. Any of known configurations commonly used in the field of the organic EL display can be used without limitation for other configurations.

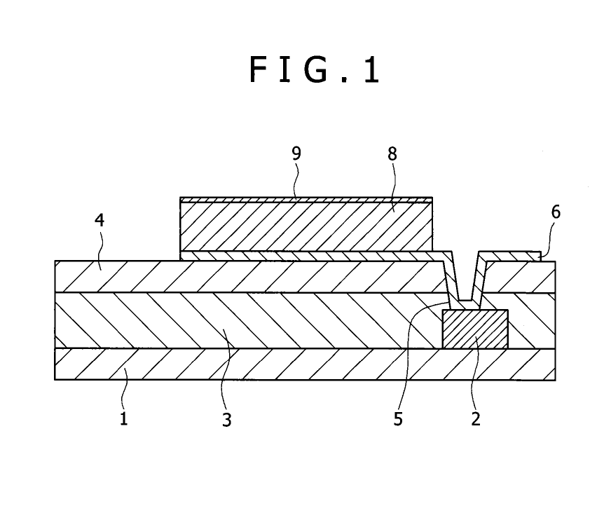

Summary of an embodiment of the organic EL display including the reflective anode electrode of the present invention is now described with FIG. 1. However, the invention should not be limited to the organic EL display illustrated in FIG. 1, and any of configurations typically used in the art can be appropriately used.

In this embodiment, TFT 2 and a passivation film 3 are formed on a substrate 1, and a planarization layer 4 is formed on the passivation film 3. A contact hole 5 is formed on the TFT 2, and a source/drain electrode (not shown) of the TFT 2 is electrically connected to the Al alloy film (reflective film) 6 through the contact hole 5. In the invention, the Al alloy film 6 configures the reflective anode electrode. The reason why the Al alloy film 6 is referred to as reflective anode electrode is because the Al alloy film 6 serves as a reflective electrode of the organic EL device, and further serves as an anode electrode since it is electrically connected to the source/drain electrode of the TFT 2. Alternatively, the reflective anode electrode may be equal to the source/drain electrode. Such a configuration also exhibits the effects of the invention.

An organic light-emitting layer 8 is formed directly on the Al alloy film 6, and a cathode electrode 9 is formed on the organic light-emitting layer 8. Specifically, while a traditional organic EL display has an oxide conductive film between the Al alloy film 6 and the organic light-emitting layer 8, the organic EL display of FIG. 1 including the reflective anode electrode of the invention does not require the oxide conductive film. In this embodiment, the predetermined Al alloy film 6 is used; hence, even if the Al alloy film 6 is directly connected to the organic light-emitting layer 8, variations in light emitting characteristics are suppressed. In addition, such an organic EL display achieves high emission luminance since light emitted from the organic light-emitting layer 8 is efficiently reflected by the reflective anode electrode of the invention.

### EXAMPLES

Although the invention is now described in detail with Examples, the invention should not be limited thereto, and modifications or alterations thereof may be made within the scope without departing from the gist described before and later, all of which are included in the technical scope of the invention.

### Example 1

Alkali-free glass plates, each being 0.7 mm in thickness and 4 inches in diameter, were used as substrates, and Al alloy films (each having a thickness of about 500 nm), which were different from one another in type and content of a rare earth element as shown in Table 1 (in atomic percent, the remainder: Al and inevitable impurities), were formed on the substrates by a DC magnetron sputtering process. After the atmosphere in the deposition chamber was temporarily evacuated to the ultimate vacuum of 1×10⁻⁶ Torr, each Al alloy film was deposited under the following conditions using a disc target, which had a diameter of 4 inches and the same composition as that of each Al alloy film. Subsequently, the deposited Al alloys were subjected to annealing for 15 min in a nitrogen atmosphere at various annealing temperatures shown in Table 1. In Table 1, “-” refers to unheated (i.e., room temperature). The compositions of the resultant Al alloy films were identified by inductively coupled plasma (ICP) mass spectrometry.

### (Sputtering Conditions)

Ar gas pressure: 1 mTorr

Ar gas flow rate: 20 sccm

Sputtering power: 130 W

Deposition temperature: 100° C.

The Al alloy films produced in the above manner were subjected to a film hardness test using a nano-indenter. In this test, each Al alloy film was subjected to continuous stiffness measurement using an XP tip with Nano Indenter XP from MTS System Corporation (analysis software: Test Works 4). Measurement was performed at 15 points under a condition of indentation depth of 300 nm, excitation oscillation frequency of 45 Hz, and amplification of 2 nm, and the average of the resultant values was obtained.

Moreover, in the test, measurement was performed with the indentation depth of 20 nm, and then the surface of each Al alloy film was observed by a light microscope (of 1000 magnifications) to check presence of deformation due to plastic deformation.

Furthermore, the Al alloy films produced in the above manner were subjected to TEM observation at a magnification of 150,000× to measure the density (triple point density) of Al alloy at a grain boundary triple point observed in each of measured visual fields (each visual field being 1.2 μm×1.6 μm). Such measurement was performed in three visual fields in total, and the average of the measured values was determined as the triple point density of the Al alloy.

Samples, each having a pure Al film in place of the Al alloy film, were also subjected to measurement of the hardness and the triple point density in the same way as above.

Table 1 collectively shows results of such measurement. In Table 1, “E+07” refers to 10⁷. For example, “9.0E+07” in No. 101 in Table 1 refers to 9.0×10⁷.

TABLE 1

| | | Annealing | Triple | Hard- | Presence |
|---|---|---|---|---|---|
| | Compo- | temperature | point density | ness | of defor- |
| No. | sition | (° C.) | (number/mm²) | (GPa) | mation |
| 101 | Pure Al | — | 9.0E+07 | 0.9 | X |
| 102 | Pure Al | 150 | 5.9E+07 | 0.9 | X |
| 103 | Pure Al | 250 | 5.6E+07 | 0.9 | X |
| 104 | Pure Al | 300 | 2.9E+07 | 0.9 | X |
| 105 | Al—0.05Nd | — | 2.5E+08 | 2.4 | ◯ |
| 106 | Al—0.05Nd | 150 | 2.4E+08 | 2.3 | ◯ |
| 107 | Al—0.05Nd | 200 | 2.4E+08 | 2.1 | ◯ |
| 108 | Al—0.05Nd | 250 | 1.2E+08 | 1.1 | X |
| 109 | Al—0.2Nd | — | 3.2E+08 | 2.9 | ◯ |
| 110 | Al—0.2Nd | 150 | 2.6E+08 | 2.6 | ◯ |
| 111 | Al—0.2Nd | 200 | 2.5E+08 | 2.5 | ◯ |
| 112 | Al—0.2Nd | 250 | 1.2E+08 | 1.2 | X |
| 113 | Al—0.6Nd | — | 3.6E+08 | 3.2 | ◯ |
| 114 | Al—0.6Nd | 150 | 3.0E+08 | 3.1 | ◯ |
| 115 | Al—0.6Nd | 200 | 2.8E+08 | 2.7 | ◯ |
| 116 | Al—0.6Nd | 230 | 2.1E+08 | 2.1 | ◯ |
| 117 | Al—0.6Nd | 250 | 1.3E+08 | 1.2 | X |
| 118 | Al—0.6Nd | 300 | 5.0E+07 | 1.1 | X |
| 119 | Al—0.2Gd | — | 3.2E+08 | 3.1 | ◯ |
| 120 | Al—0.2Gd | 150 | 2.7E+08 | 2.7 | ◯ |
| 121 | Al—0.2Gd | 200 | 2.5E+08 | 2.4 | ◯ |
| 122 | Al—0.2La | — | 3.3E+08 | 3.0 | ◯ |
| 123 | Al—0.2La | 150 | 2.6E+08 | 2.6 | ◯ |
| 124 | Al—0.2La | 200 | 2.4E+08 | 2.4 | ◯ |
| 125 | Al—0.2Y | — | 3.1E+08 | 2.9 | ◯ |
| 126 | Al—0.2Y | 150 | 2.5E+08 | 2.6 | ◯ |
| 127 | Al—0.2Y | 200 | 2.4E+08 | 2.4 | ◯ |
| 128 | Al—0.2Ce | — | 3.2E+08 | 3.0 | ◯ |
| 129 | Al—0.2Ce | 150 | 2.7E+08 | 2.6 | ◯ |
| 130 | Al—0.2Ce | 200 | 2.5E+08 | 2.5 | ◯ |
| 131 | Al—0.2Pr | — | 3.2E+08 | 3.0 | ◯ |
| 132 | Al—0.2Pr | 150 | 2.6E+08 | 2.7 | ◯ |
| 133 | Al—0.2Pr | 200 | 2.4E+08 | 2.4 | ◯ |
| 134 | Al—0.2Dy | — | 3.1E+08 | 2.9 | ◯ |
| 135 | Al—0.2Dy | 150 | 2.5E+08 | 2.6 | ◯ |
| 136 | Al—0.2Dy | 200 | 2.4E+08 | 2.4 | ◯ |
| 137 | Al—5.0Nd | — | 1.9E+09 | 14.7 | ◯ |
| 138 | Al—5.0Nd | 150 | 8.9E+08 | 9.2 | ◯ |
| 139 | Al—5.0Nd | 200 | 5.7E+08 | 5.3 | ◯ |

In Table 1, Nos. 105 to 118 and 137 to 139 are each an example of an Al alloy film containing Nd as the rare earth element. Table 1 shows that in the case of the same annealing temperature, hardness and triple point density each tend to increase with increase in Nd content (for example, a case where annealing temperature is room temperature “-”, see Nos. 105, 109, 113, and 137), and the upper limit of the Nd content is effectively specified to be 1 at % in order to control each of the hardness and the triple point density to be within a predetermined range. Table 1 further shows that even in the case of the same Nd content, if annealing temperature exceeds the preferable range of the invention, each of the hardness and the triple point density tends to decrease (for example, a case where annealing temperature is 250° C., see Nos. 108, 112, and 117), and deformation occurs due to plastic deformation; hence, the upper limit of the annealing temperature is effectively specified to be 230° C. in order to control each of the hardness and the triple point density to be within a predetermined range to eliminate the deformation due to plastic deformation.

In Table 1, Nos. 119 to 136 are each an example using an Al alloy film containing a rare earth element other than Nd. Each of the example Al alloy films contained a rare earth element in the amount specified in the invention, and was fabricated while the annealing temperature was controlled to be within the preferable range of the invention; hence, the hardness and the triple point density were each controlled to be within the range of the invention. It has been experimentally confirmed that even if the rare earth element other than Nd is used, experimental results similar to those in the case using Nd are given (not shown in Table 1).

These results reveal that when the Al-rare earth element alloy film of the invention is used, a highly reliable, reflective anode electrode for organic EL displays can be promisingly provided, the reflective anode electrode being excellent in durability against longitudinal stress, and being less likely to cause disconnection and temporal increase in electric resistance.

In contrast, Nos. 101 to 104 are examples using pure Al containing no rare earth element, in which the hardness and the triple point density were not able to be controlled into those specified in the invention no matter how the annealing temperature was controlled. In addition, deformation due to plastic deformation occurred in any of such examples.

### Example 2

Alkali-free glass plates, each being 0.7 mm in thickness and 4 inches in diameter, were used as substrates, and Al alloy films (each having a thickness of about 600 nm), which were different from one another in type and content of a rare earth element as shown in Table 2, were formed on the substrates by a DC magnetron sputtering process. After the atmosphere in the deposition chamber was temporarily evacuated to the ultimate vacuum of 1×10⁻⁶ Torr, each Al alloy film was deposited using a disc target, which had a diameter of 4 inches and the same composition as that of each Al alloy film, while deposition temperature and Ar gas pressure (shown as Ar pressure in Table 2) were each variously varied as shown in Table 2. Other sputtering conditions are as shown below. The deposited Al alloys were subjected to annealing for 30 min in a nitrogen atmosphere at various annealing temperatures shown in Table 2. In Table 2, “-” refers to unheated (i.e., room temperature). The compositions of the resultant Al alloy films were identified by ICP mass spectrometry as with the Example 1.

### (Sputtering Conditions)

Ar gas flow rate: 30 sccm

Sputtering power: 260 W

Deposition temperature: room temperature

The Al alloy films produced in the above manner were subjected to a film hardness test using a nano-indenter, and Young's moduli were determined. In this test, each Al alloy film was subjected to continuous stiffness measurement using an XP tip with Nano Indenter G200 from Agilent Technologies Co., Ltd (analysis software: Test Works 4). Measurement was performed at 15 points with indentation depth of 500 nm.

Moreover, in the test, measurement was performed with the indentation depth of 20 nm, and then the surface of each Al alloy film was observed by a light microscope (of 1000 magnifications) to check presence of deformation due to plastic deformation.

Furthermore, the Al alloy films produced in the above manner were subjected to TEM observation at a magnification of 150,000× to measure grain size of each crystal grain (one-direction tangential diameter, or Feret diameter) observed in each of measured visual fields (each visual field being 1.2 μm×1.6 μm). Such measurement was performed in three visual fields in total, and the maximum of the measured values in the three visual fields was determined as the maximum grain size.

Samples, each having a pure Al film in place of the Al alloy film, were also subjected to measurement of the Young's modulus and the maximum grain size in the same way as above.

Table 2 collectively shows results of such measurement.

TABLE 2

| | | Deposition | | Annealing | Young's | Maximum | |
|---|---|---|---|---|---|---|---|
| | | temperature | Ar pressure | temperature | modulus | grain size | Presence of |
| No. | Composition | (° C.) | (mTorr) | (° C.) | (GPa) | (nm) | deformation |
| 201 | Pure Al | 25 | 2 | — | 71 | 412 | X |
| 202 | Pure Al | 25 | 2 | 150 | 73 | 593 | X |
| 203 | Pure Al | 25 | 2 | 300 | 71 | 1066 | X |
| 204 | Al—0.05Nd | 25 | 2 | — | 86 | 161 | ◯ |
| 205 | Al—0.05Nd | 25 | 2 | 150 | 85 | 170 | ◯ |
| 206 | Al—0.05Nd | 25 | 2 | 200 | 84 | 179 | ◯ |
| 207 | Al—0.2Nd | 25 | 2 | — | 91 | 158 | ◯ |
| 208 | Al—0.2Nd | 25 | 2 | 150 | 88 | 165 | ◯ |
| 209 | Al—0.2Nd | 25 | 2 | 200 | 87 | 167 | ◯ |
| 210 | Al—0.6Nd | 25 | 2 | — | 95 | 140 | ◯ |
| 211 | Al—0.6Nd | 25 | 2 | 150 | 94 | 142 | ◯ |
| 212 | Al—0.6Nd | 25 | 2 | 200 | 89 | 148 | ◯ |
| 213 | Al—0.6Nd | 100 | 2 | 200 | 86 | 166 | ◯ |
| 214 | Al—0.6Nd | 200 | 2 | 200 | 82 | 320 | ◯ |
| 215 | Al—0.6Nd | 25 | 0.8 | 200 | 93 | 125 | ◯ |
| 216 | Al—0.6Nd | 25 | 10 | 200 | 84 | 188 | ◯ |
| 217 | Al—0.6Nd | 25 | 20 | 200 | 80 | 255 | ◯ |
| 218 | Al—0.6Nd | 25 | 2 | 230 | 83 | 188 | ◯ |
| 219 | Al—0.6Nd | 25 | 2 | 300 | 72 | 427 | X |
| 220 | Al—5.0Nd | 25 | 2 | — | 197 | 142 | ◯ |
| 221 | Al—5.0Nd | 25 | 2 | 150 | 139 | 143 | ◯ |
| 222 | Al—5.0Nd | 25 | 2 | 200 | 110 | 149 | ◯ |
| 223 | Al—0.2Gd | 25 | 2 | — | 93 | 139 | ◯ |
| 224 | Al—0.2Gd | 25 | 2 | 150 | 90 | 144 | ◯ |
| 225 | Al—0.2Gd | 25 | 2 | 200 | 87 | 145 | ◯ |
| 226 | Al—0.2La | 25 | 2 | — | 92 | 148 | ◯ |
| 227 | Al—0.2La | 25 | 2 | 150 | 88 | 147 | ◯ |
| 228 | Al—0.2La | 25 | 2 | 200 | 86 | 159 | ◯ |
| 229 | Al—0.2Y | 25 | 2 | — | 91 | 146 | ◯ |
| 230 | Al—0.2Y | 25 | 2 | 150 | 88 | 149 | ◯ |
| 231 | Al—0.2Y | 25 | 2 | 200 | 86 | 163 | ◯ |
| 232 | Al—0.2Ce | 25 | 2 | — | 92 | 150 | ◯ |
| 233 | Al—0.2Ce | 25 | 2 | 150 | 89 | 147 | ◯ |
| 234 | Al—0.2Ce | 25 | 2 | 200 | 87 | 162 | ◯ |
| 235 | Al—0.2Pr | 25 | 2 | — | 92 | 144 | ◯ |
| 236 | Al—0.2Pr | 25 | 2 | 150 | 89 | 148 | ◯ |
| 237 | Al—0.2Pr | 25 | 2 | 200 | 87 | 158 | ◯ |
| 238 | Al—0.2Dy | 25 | 2 | — | 91 | 148 | ◯ |
| 239 | Al—0.2Dy | 25 | 2 | 150 | 88 | 148 | ◯ |
| 240 | Al—0.2Dy | 25 | 2 | 200 | 87 | 159 | ◯ |

In Table 2, Nos. 204 to 222 are each an example of an Al alloy film containing Nd as a rare earth element. Table 2 shows that in the case of the same sputtering condition and the same annealing temperature, as the Nd content increases, the Young's modulus tends to increase (for example, a case where annealing temperature is room temperature “-”, see Nos. 204, 207, 210, and 220), while the maximum grain size tends to somewhat decrease. Table 2 further shows that even in the case of the same Nd content and the same sputtering conditions, if annealing temperature exceeds the preferable range of the invention, the Young's modulus decreases, and the maximum grain size increases, and thus deformation occurs due to plastic deformation (for example, see Nos. 218 and 219); hence, the upper limit of the annealing temperature is effectively specified to be 230° C. in order to control each of the Young's modulus and the maximum grain size to be within a predetermined range to eliminate the deformation due to plastic deformation.

In Table 2, Nos. 223 to 240 are each an example using an Al alloy film containing a rare earth element other than Nd. Each of the example Al alloy films contained a rare earth element in the amount specified in the invention, and was fabricated while the sputtering conditions and the annealing temperature were each controlled to be within the preferable range of the invention; hence, the Young's modulus and the maximum grain size were each controlled to be within the range of the invention. It has been experimentally confirmed that even if the rare earth element other than Nd is used, experimental results similar to those in the case using Nd are given (not shown in Table 2).

These results reveal that when the Al-rare earth element alloy film of the invention is used, a highly reliable organic EL can be promisingly provided, the organic EL display being excellent in durability against lateral stress, and being less likely to cause disconnection and temporal increase in electric resistance.

In contrast, Nos. 201 to 203 are examples using pure Al containing no rare earth element, in which the Young's modulus and the maximum grain size were not able to be controlled into those specified in the invention regardless of the annealing temperature. In addition, deformation due to plastic deformation occurred in any of such examples.

### Example 3

Alkali-free glass plates, each being 0.7 mm in thickness and 4 inches in diameter, were used as substrates, and Al alloy films (each having a thickness of about 100 nm), which were different from one another in type and content of a rare earth element as shown in Table 3 (in atomic percent, the remainder: Al and inevitable impurities), were formed on the substrates by a DC magnetron sputtering process. After the atmosphere in the deposition chamber was temporarily evacuated to the ultimate vacuum of 3×10⁻⁶ Torr, each Al alloy film was deposited using a disc target, which had a diameter of 4 inches and the same composition as that of each Al alloy film, while deposition temperature and Ar gas pressure (shown as Ar pressure in Table 3) were each variously varied as shown in Table 3. Other sputtering conditions are as shown below. Subsequently, the deposited Al alloys were subjected to annealing for 30 min in a nitrogen atmosphere at various annealing temperatures shown in Table 3. In Table 3, “-” refers to unheated (i.e., room temperature). The compositions of the resultant Al alloy films were identified by ICP mass spectrometry.

### (Sputtering Conditions)

Ar gas flow rate: 30 sccm

Sputtering power: 130 W

Deposition temperature: room temperature

The Al alloy films produced in the above manner were subjected to measurement of 60° specular glossiness in accordance with JIS K7105-198. The glossiness was represented by a value (%) obtained assuming that glossiness of the surface of glass having a refractive index of 1.567 was 100.

Furthermore, the aluminum alloy films produced in the above manner were used to evaluate a level of etching characteristics. In detail, each Al alloy film was immersed in a mixed-acid etchant (phosphoric acid:nitric acid:acetic acid:water=70:2:10:18) warmed to 40° C. to perform etching for a period (over etching time) corresponding to a period 1.5 times as long as the etching completion time. After the etching, each glass substrate was observed by a light microscope (of 1000 magnifications) and SEM (of 30,000 magnifications). It was defined that an Al alloy film, on which no etching characteristic was found in either observation, was ∘, an Al alloy film, on which an etching characteristic was found only in SEM observation, was A, and an Al alloy film, on which an etching characteristic was found in each of SEM observation and light microscope observation, was x. In the Example 3, ∘ or Δ is determined to be good in etching characteristic.

Samples, each having a pure Al film in place of the Al alloy film, were also subjected to measurement of glossiness and evaluation of a level of etching characteristics in the same way as above.

Table 3 collectively shows results of such measurement. While Table 3 shows results of the glossiness after heat treatment (annealing), it has been confirmed that such values of the glossiness are almost not different from those of glossiness immediately after deposition (before annealing).

TABLE 3

| | | Deposition | | Annealing | | |
|---|---|---|---|---|---|---|
| | | temperature | Ar pressure | temperature | Glossiness | Etching |
| No. | Composition | (° C.) | (mTorr) | (° C.) | (%) | characteristic |
| 301 | Pure Al | 25 | 2 | — | 786 | ◯ |
| 302 | Pure Al | 25 | 2 | 150 | 771 | ◯ |
| 303 | Pure Al | 25 | 2 | 300 | 763 | ◯ |
| 304 | Al—0.02Nd | 25 | 2 | — | 791 | ◯ |
| 305 | Al—0.05Nd | 25 | 2 | — | 810 | ◯ |
| 306 | Al—0.2Nd | 25 | 2 | — | 817 | ◯ |
| 307 | Al—0.6Nd | 25 | 2 | — | 825 | ◯ |
| 308 | Al—0.6Nd | 100 | 2 | — | 822 | ◯ |
| 309 | Al—0.6Nd | 200 | 2 | — | 815 | ◯ |
| 310 | Al—0.6Nd | 250 | 2 | — | 808 | ◯ |
| 311 | Al—0.6Nd | 270 | 2 | — | 802 | ◯ |
| 312 | Al—0.6Nd | 25 | 10 | — | 815 | ◯ |
| 313 | Al—0.6Nd | 25 | 15 | — | 806 | ◯ |
| 314 | Al—0.6Nd | 25 | 20 | — | 797 | ◯ |
| 315 | Al—0.6Nd | 25 | 2 | 150 | 826 | ◯ |
| 316 | Al—0.6Nd | 25 | 2 | 300 | 823 | ◯ |
| 317 | Al—3.0Nd | 25 | 2 | — | 827 | ◯ |
| 318 | Al—5.0Nd | 25 | 2 | — | 831 | Δ |
| 319 | Al—0.2Gd | 25 | 2 | — | 819 | ◯ |
| 320 | Al—0.2La | 25 | 2 | — | 814 | ◯ |
| 321 | Al—0.2Y | 25 | 2 | — | 807 | ◯ |
| 322 | Al—0.2Ce | 25 | 2 | — | 817 | ◯ |
| 323 | Al—0.2Pr | 25 | 2 | — | 817 | ◯ |
| 324 | Al—0.2Dy | 25 | 2 | — | 816 | ◯ |

In Table 3, Nos. 304 to 318 are each an example of an Al alloy film containing Nd as a rare earth element. Table 3 shows that in the case of the same sputtering condition and the same annealing temperature, as the Nd content increases, the glossiness tends to increase (for example, a case where annealing temperature is room temperature “-”, see Nos. 304, 305, 306, 307, 317, and 318). While etching characteristics are increasingly observed with increase in Nd content, the level of the etching characteristics was acceptable within a range of the Nd content not more than the upper limit (5 at %) specified in the invention. The glossiness is also deeply related with the sputtering conditions. The desired glossiness (800% or more) was not exhibited by No. 314 that was produced under a condition of the Ar gas pressure beyond the preferable range of the invention. The glossiness is also deeply related with the deposition temperature, and the glossiness tends to be reduced at a higher deposition temperature. It was however confirmed that the desired glossiness (800% or more) was given even at 270° C. being over a typical process temperature. Furthermore, while Nos. 307, 315, and 316 are cases of Al alloy films containing 0.6 at % Nd, which were formed by sputtering under the same conditions except for annealing temperature (annealing temperatures of Nos. 307, 315, and 316 were annealing skipped room temperature, 150° C., and 300° C., respectively), the glossiness is substantially the same (about 820%) therebetween, showing that glossiness is almost not affected by annealing.

The above experimental results reveal that in order to achieve the predetermined glossiness, it is effective that the upper limit of Nd content is specified to be 5 at %, and the sputtering conditions are controlled such that the deposition temperature is 270° C. or less, and the Ar gas pressure is 15 mTorr or less.

In Table 3, Nos. 319 to 324 are each an example using an Al alloy film containing a rare earth element other than Nd. Each of the example Al alloy films contained a rare earth element in the amount specified in the invention, and was fabricated while the sputtering conditions were each controlled to be within the preferable range of the invention; hence, the glossiness was controlled to be within the range of the invention. It has been experimentally confirmed that even if the rare earth element other than Nd is used, experimental results similar to those in the case using Nd are given (not shown in Table 3).

These results reveal that when the Al-rare earth element alloy film of the invention is used, an organic EL display, which is high in glossiness and is excellent in color expression power, can be promisingly provided.

In contrast, Nos. 301 to 303 are examples using pure Al containing no rare earth element, in which the glossiness was not able to be controlled to be in the range of glossiness specified in the invention while the sputtering conditions were each controlled to be within the preferable range of the invention.

Although the application has been described in detail with reference to particular embodiments, it should be understood by those skilled in the art that various alterations and modifications thereof may be made without departing from the spirit and the scope of the invention.

The present application is based on Japanese patent application (JP-2011-116304) filed on May 24, 2011, Japanese patent application (JP-2011-116305) filed on May 24, 2011, and Japanese patent application (JP-2011-116306) filed on May 24, 2011, the contents of all of which are hereby incorporated by reference.

### INDUSTRIAL APPLICABILITY

According to the present invention, an Al alloy film, which contains a rare earth element and is appropriately controlled in hardness and in density of grain boundary triple points, is used as an Al alloy film configuring a reflective anode electrode for organic EL displays, and therefore the Al alloy film is particularly excellent in durability against longitudinal stress such as an indentation load. In addition, since the Al alloy film is appropriately controlled in Young's modulus and in maximum grain boundary of one-direction tangential diameter (Feret diameter) of a crystal grain, the Al alloy film is also excellent in durability against lateral deformation. As a result, even if the Al reflective film is directly connected to the organic layer, stable emission characteristics can be ensured, so that a highly reliable reflective anode electrode for organic EL displays has been able to be provided. Furthermore, since the Al alloy film is excellent in glossiness, a reflective anode electrode for organic EL displays, which is excellent in color expression power, has been able to be provided. The organic EL display of the present invention is preferably used for, for example, a mobile phone, a portable video game player, a tablet computer, and a television.

### DESCRIPTION OF THE REFERENCE NUMERALS AND SIGNS

1 substrate
2 TFT
3 passivation film
4 planarization layer
5 contact hole
6 Al alloy film (reflective film)
8 organic light-emitting layer
9 cathode electrode

1. An interconnection structure including, on a substrate, an Al alloy film configuring a reflective anode electrode for organic EL displays and an organic layer containing a light emitting layer, the interconnection structure being characterized in that
the Al alloy film contains at least one rare earth element in an amount of 0.05 to 5 at %, the rare earth element being selected from a group consisting of Nd, Gd, La, Y, Ce, Pr, and Dy, and
the organic layer is directly connected onto the Al alloy film.

2. The interconnection structure according to claim 1, characterized in that the Al alloy film has a hardness of 2 to 3.5 GPa and a density of grain boundary triple points in an Al alloy structure of 2×10⁸/mm² or more.

3. The interconnection structure according to claim 1, characterized in that the Al alloy film has a Young's modulus of 80 to 200 GPa and a maximum value of one-direction tangential diameter (Feret diameter) of a crystal grain of 100 to 350 nm.

4. The interconnection structure according to claim 1, characterized in that the Al alloy film has a glossiness of 800% or more.

5. The interconnection structure according to claim 1, wherein the Al alloy film is electrically connected to a source/drain electrode of a thin film transistor formed on the substrate.

6. A thin film transistor substrate, comprising the interconnection structure according to claim 1.

7. An organic EL display, comprising the thin film transistor substrate according to claim 6.
